(19) United States
(12) Patent Application Publication
(10) Pub. No.: US 2025/0155656 A1
(43) Pub. Date: May 15, 2025

(54) OPTOELECTRONIC STRUCTURE

(71) Applicant: Advanced Semiconductor Engineering, Inc., Kaohsiung (TW)

(72) Inventors: Jr-Wei LIN, Kaohsiung (TW); Mei-Ju LU, Kaohsiung (TW); Pei-Jung YANG, Kaohsiung (TW)

(73) Assignee: Advanced Semiconductor Engineering, Inc., Kaohsiung (TW)

(21) Appl. No.: 18/506,094

(22) Filed: Nov. 9, 2023

(51) Int. Cl. G02B 6/42; H01S 5/00; H01S 5/02315

(52) U.S. Cl. CPC G02B 6/4206; H01S 5/0071; H01S 5/02315

(57) ABSTRACT

An optoelectronic structure is provided. The optoelectronic structure includes a carrier, a first optical component, and a second optical component. The first optical component is supported by the carrier. The second optical component is supported by the first optical component and optically coupled to the first optical component.

### BACKGROUND

### 1. Technical Field

The present disclosure relates generally to an optoelectronic structure.

### 2. Description of the Related Art

Light source modules are normally manufactured by assembling optical elements/components by active alignment, after which the light source module is actively aligned with a photonic component to form a package. In the active alignment process, the light source module transmits an optical signal directly to the photonic component, and the optical signal received by the photonic component is monitored when the light source module continues changing position. The light source module must be turned on and moved until an optimum optical signal is monitored by the photonic component to complete the active alignment process.

### SUMMARY

In one or more arrangements, an optoelectronic structure includes a carrier, a first optical component, and a second optical component. The first optical component is supported by the carrier. The second optical component is supported by the first optical component and optically coupled to the first optical component.

In one or more arrangements, an optoelectronic structure includes a first optical component, a second optical component, and an optical guiding structure. The second optical component is disposed over the first optical component. The optical guiding structure is configured to couple an optical signal from the second optical component to the first optical component and further configured to direct the optical signal at least twice within an elevation range horizontally overlapped with the second optical component.

In one or more arrangements, an optoelectronic structure includes a first optical component and a second optical component. The second optical component is overlapped with the first optical component. The first optical component is configured to edge couple an optical signal from the second optical component.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A is a cross-section of an optoelectronic structure in accordance with some arrangements of the present disclosure.

FIG. 1B is a top view of an optoelectronic structure in accordance with some arrangements of the present disclosure.

FIG. 1C is a cross-section of an optoelectronic structure in accordance with some arrangements of the present disclosure.

FIG. 1D is a top view of an optoelectronic structure in accordance with some arrangements of the present disclosure.

FIG. 2A is a cross-section of an optoelectronic structure in accordance with some arrangements of the present disclosure.

FIG. 2B is a top view of an optoelectronic structure in accordance with some arrangements of the present disclosure.

FIG. 3A is a cross-section of an optoelectronic structure in accordance with some arrangements of the present disclosure.

FIG. 3B is a top view of an optoelectronic structure in accordance with some arrangements of the present disclosure.

FIG. 3C is a top view of an optoelectronic structure in accordance with some arrangements of the present disclosure.

FIG. 3D is a cross-section of an optoelectronic structure in accordance with some arrangements of the present disclosure.

FIG. 3E is a cross-section of an optoelectronic structure in accordance with some arrangements of the present disclosure.

FIG. 4A is a cross-section of an optoelectronic structure in accordance with some arrangements of the present disclosure.

FIG. 4B is a top view of an optoelectronic structure in accordance with some arrangements of the present disclosure.

FIG. 5A is a cross-section of an optoelectronic structure in accordance with some arrangements of the present disclosure.

FIG. 5B is a top view of an optoelectronic structure in accordance with some arrangements of the present disclosure.

FIG. 5C is a cross-section of an optoelectronic structure in accordance with some arrangements of the present disclosure.

FIG. 6A is a cross-section of an optoelectronic structure in accordance with some arrangements of the present disclosure.

FIG. 6B is a top view of an optoelectronic structure in accordance with some arrangements of the present disclosure.

FIG. 7A, FIG. 7B, and FIG. 7C illustrate various stages of an exemplary method for manufacturing an optoelectronic structure in accordance with some arrangements of the present disclosure.

Common reference numerals are used throughout the drawings and the detailed description to indicate the same or similar elements.

### DETAILED DESCRIPTION

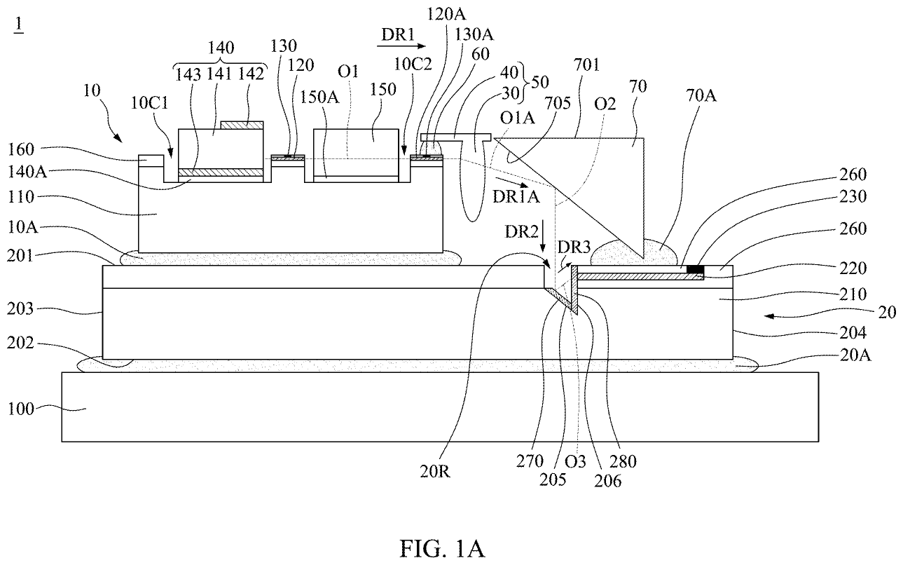

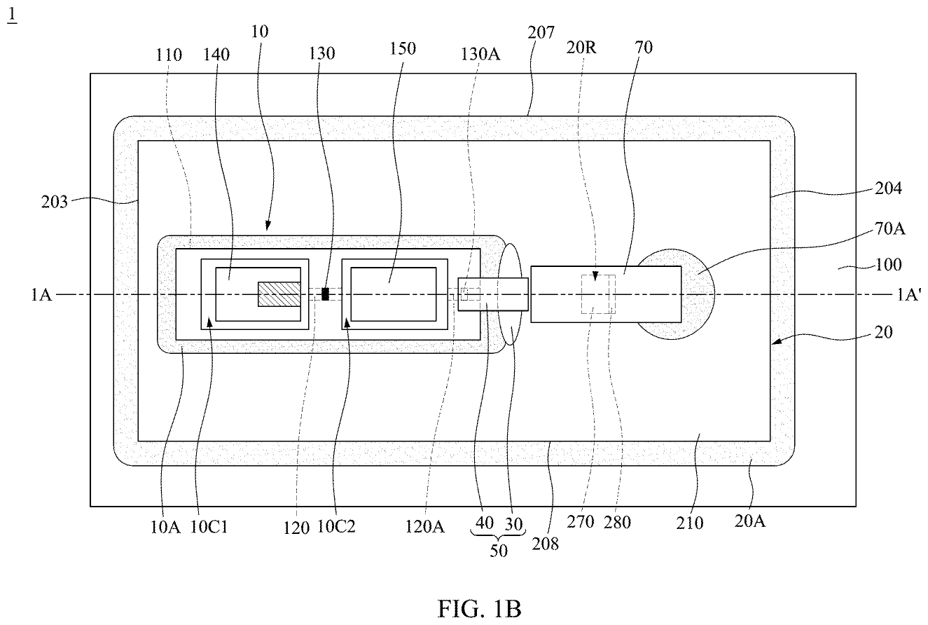

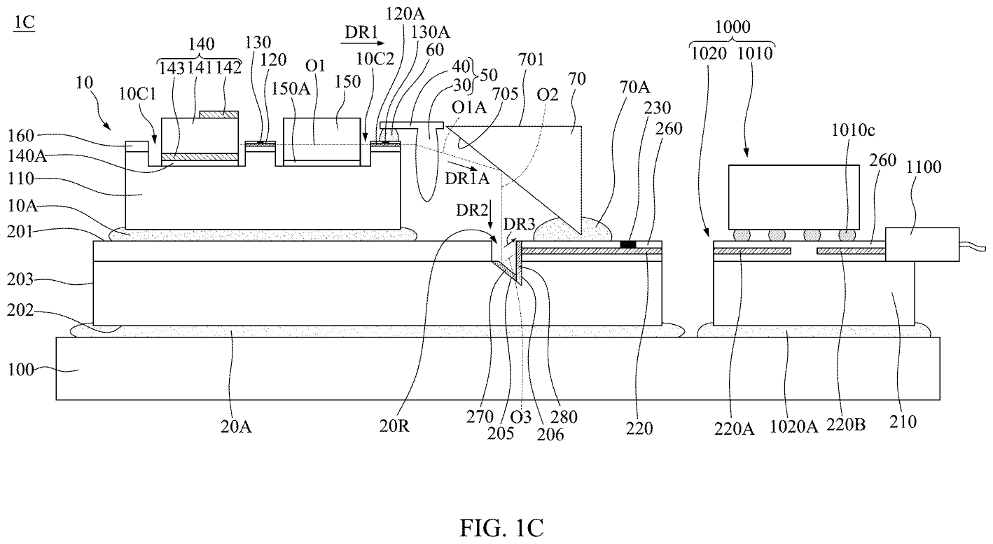

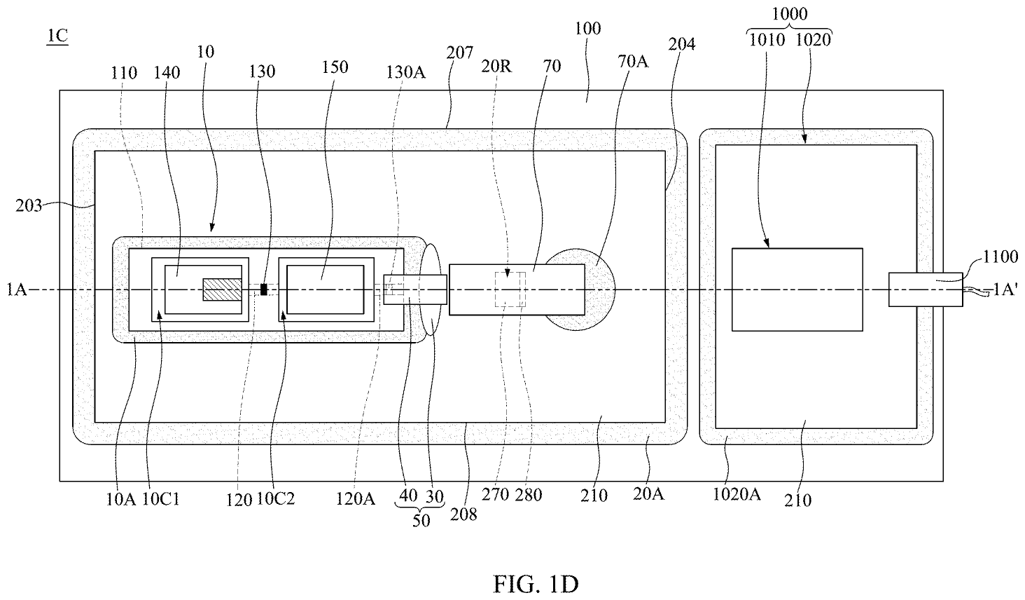

FIG. 1A is a cross-section of an optoelectronic structure 1 in accordance with some arrangements of the present disclosure. FIG. 1B is a top view of an optoelectronic structure 1 in accordance with some arrangements of the present disclosure. In some arrangements, FIG. 1A is a cross-section along a line 1A-1A′ in FIG. 1B. The optoelectronic structure 1 may include a substrate 100 and a plurality of optical components disposed over the substrate 100. The optical components may include a light source module 10, a photonic component 20, a lens structure 50, and an optical guiding element 70.

The substrate 100 may be or include a carrier. The substrate 100 may include, for example, a printed circuit board, such as a paper-based copper foil laminate, a composite copper foil laminate, or a polymer-impregnated glass-fiber-based copper foil laminate. The substrate 100 may include an interconnection structure, which may include such as a plurality of conductive traces and/or a plurality of conductive vias. The interconnection structure may include a redistribution layer (RDL) and/or a grounding element. In some arrangements, the substrate 100 may include an organic substrate or a leadframe. In some arrangements, the substrate 100 may include a ceramic material or a metal plate. In some arrangements, the substrate 100 may include a two-layer substrate which includes a core layer and a conductive material and/or structure disposed on an upper surface and a bottom surface of the substrate. The substrate 100 may include a semiconductor wafer or an electronic component. The electronic component may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof. In some arrangements, the substrate 100 may include one or more conductive elements, surfaces, contacts, or pads.

The light source module 10 may be disposed over the substrate 100. In some arrangements, the light source module 10 is electrically connected to the substrate 100. The light source module 10 may be supported by the substrate 100 (or the carrier). In some arrangements, the light source module 10 is disposed over (e.g., affixed to) the photonic component 20 by an adhesive element 10A. The light source module 10 may be overlapped with the photonic component 20. The light source module 10 may be optically coupled to the photonic component 20. In some arrangements, the light source module 10 includes a substrate layer 110, waveguides 120 and 120A, photodetectors 130 and 130A, a light source 140, an active optical element 150, and a dielectric layer 160. The substrate layer 110 may include a silicon-based layer and one or more circuit layers formed in the silicon-based layer. The circuit layers may include a driver circuit (e.g., a laser diode driver circuit). The substrate layer 110 and the dielectric layer 160 collectively define cavities 10C1 and 10C2. The waveguides 120 and 120A may be formed on the dielectric layer 160, and the photodetectors 130 and 130A may be formed over the dielectric layer 160 and optically coupled to the waveguides 120 and 120A, respectively. The photodetector 130 may be configured to detect one or more optical signals transmitted through the waveguide 120, and the photodetector 130A may be configured to detect one or more optical signals transmitted through the waveguide 120A. The dielectric layer 160 may serve as a protective layer or a passivation layer for the waveguides 120 and 120A and the photodetectors 130 and 130A. The light source 140 may be configured to provide an optical signal for the photonic component 20. The optical signal from the light source 140 may be or include light without any logic signal. The light source 140 may be or include a laser diode. The light source 140 may include a light-emitting layer 141 and electrodes 142 and 143. The light source 140 may be adhered to a bottom of the cavity 10C1 by an adhesive layer 140A. The active optical element 150 may be adhered to a bottom of the cavity 10C2 by an adhesive layer 150A. The active optical element 150 may include an amplifier, e.g., a semiconductor optical amplifier (SOA). The active optical element 150 may be passively aligned by the waveguide 120 and/or 120A.

The photonic component 20 may be disposed over the substrate 100. The photonic component 20 may be supported by the light source module 10. In some arrangements, the photonic component 20 is disposed between the substrate 100 and the light source module 10. In some arrangements, the photonic component 20 is attached or affixed to the substrate 100 by an adhesive elements 20A. In some arrangements, the light source module 10 is stacked over the photonic component 20. In some arrangements, the light source module 10 is stacked over a surface 201 (or a top surface) of the photonic component 20. In some arrangements, the photonic component 20 includes a substrate layer 210, a waveguide 220, a photodetector 230, and a dielectric layer 260. The substrate layer 210 may include a silicon-based layer and one or more circuit layers formed in the silicon-based layer. The circuit layers may include a driver circuit (e.g., a photonic integrated circuit). The waveguide 220 may be formed on a portion of the substrate layer 210, and the photodetector 230 may be formed on and optically coupled to the waveguide 220. The photodetector 230 may be configured to detect and/or monitor one or more optical signals transmitted from the waveguide 220. The dielectric layer 260 may serve as a protective layer or a passivation layer for the waveguide 220 and the photodetector 230.

In some arrangements, the lens structure 50 is configured to couple an optical signal from the light source module 10 to the photonic component 20. In some arrangements, the lens structure 50 may be referred to as a collimator lens. In some arrangements, the optical signal emitted directly from the light source module may be or include a divergent light, and the lens structure 50 is configured to collimate the optical signal from a divergent light into a collimated or parallel light beam having a consistent beam size. The lens structure 50 may be referred to as an optical alignment component. In some arrangements, a propagation direction of the optical signal is changed after the optical signal passes the lens structure 50. In some arrangements, a propagation direction of the optical signal is changed from a direction DR1 (also referred to as “a first direction”) to a direction DR2 (also referred to as “a second direction”) after the optical signal passes the lens structure 50. In some arrangements, the direction DR1 is different from the direction DR2. In some arrangements, the optical signal is configured to propagate in the direction DR1 (or the first direction) along a path O1 (or an optical path) between the light source module 10 and the lens structure 50 and propagate in the direction DR2 (or the second direction) along a path O2 (or an optical path) between the lens structure 50 and the photonic component 20. In some arrangements, the optical signal is configured to propagate in the direction DR1 along the path O1 and then propagate in the direction DR2 along the path O2.

The photonic component 20 may have the surface 201 (or the top surface), a surface 202 (also referred to as “a bottom surface”) opposite to the surface 201, and surfaces 203, 204, 207, and 208 (also referred to as “lateral surfaces”) extending between the surface 201 and the surface 202. In some arrangements, the photonic component 20 has a cavity 20R (also referred to as “a recess”) recessed from the surface 201 (or the top surface) of the photonic component 20. The photonic component 20 may further have surfaces 205 and 206 (also referred to as “lateral surfaces” or “sidewalls”) adjacent to the surface 201 (or the top surface). In some arrangements, the surface 206 (or the sidewall) is inclined with respect to the surface 205, and the cavity 20R (or the recess) is defined by the surfaces 205 and 206 (or the sidewalls). The cavity 20R may be formed by dry etching. The cavity 20R may be formed by wet etching, and the surfaces 205 and 206 may be defined by the lattice planes or the crystallographic planes of the crystal structure of the substrate layer 110. An opening of the dielectric layer 260 may be formed to expose a portion of a top surface of the substrate layer 110, and the wet etching operation may be performed through the opening to form the cavity 20R.

In some arrangements, the photonic component 20 is configured to receive an optical signal from the light source module 10 through edge coupling. In some arrangements, the photonic component 20 is configured to edge couple an optical signal from the light source module 10. In some arrangements, the photonic component 20 is configured to receive an optical signal from the light source module 10 by the surface 206 (or the lateral surface). The term “edge coupling” or “edge couple” refers to coupling by an edge of a component (or an edge of a waveguide of the component) rather than by a top surface of the component (or a top surface of the waveguide of the component). For example, the photonic component 20 is configured to edge couple an optical signal from the light source module 10 by a lateral surface (e.g., the surface 206) rather than by a top surface (e.g., the surface 201). In some arrangements, the surface 205 is or includes a reflective surface configured to direct the optical signal from the light source module 10 to the surface 206 of the photonic component 20. In some arrangements, the propagation direction of the optical signal is further changed from the direction DR2 (or the second direction) to a direction DR3 (also referred to as “a third direction”) after the optical signal is reflected by the surface 205. In some arrangements, the direction DR2 is different from the direction DR3. In some arrangements, the optical signal is configured to further propagate in the direction DR3 (or the third direction) along a path O3 (or an optical path) between the surface 205 and the surface 206. In some arrangements, the optical signal is configured to propagate in the direction DR1 along the path O1, then propagate in the direction DR2 along the path O2, and then propagate in the direction DR3 along the path O3.

In some arrangements, the photonic component 20 further includes one or more elements configured to adjust the propagation direction of the optical signal. In some arrangements, the photonic component 20 further includes a reflective layer 270 and an optical isolator 280. In some arrangements, the reflective layer 270 is disposed or formed on the surface 205 (or the sidewall) configured to reflect the optical signal. In some arrangements, the reflective layer 270 is configured to adjust the propagation direction of the optical signal from the direction DR2 to the direction DR3. In some arrangements, the waveguide 220 is exposed by the surface 206 (or the lateral surface), and the optical isolator 280 is disposed on the surface 206 and configured to direct the optical signal reflected by the surface 205 to the waveguide 220. In some arrangements, the waveguide 220 directly contacts the optical isolator 280, and the optical isolator 280 is configured to receive the optical signal from the surface 205 and transmit the optical signal to the waveguide 220. The reflective layer 270 may be or include a metal layer. The optical isolator 280 may be or include glass, quartz, polymer, or other suitable material that possess a refractive index that can change a propagation direction of an optical signal (e.g., light). In some arrangements, the photonic component 20 includes an optical receiving area exposed by the light source module 10. The optical receiving area may be referred to as or include the cavity 20R, the reflective layer 270, and the optical isolator 280.

The lens structure 50 may be disposed between the light source module 10 and the photonic component 20. In some arrangements, the lens structure 50 is configured to couple the optical signal from the light source module 10 to the photonic component 20. In some arrangements, the propagation direction of the optical signal is changed after the optical signal passes the lens structure 50. In some arrangements, the light source module 10 is actively aligned with the photonic component 20 through the lens structure 50 (e.g., by adjusting the lens structure 50 to optically align the light source module 10 with the photonic component 20 during the manufacturing process). In some arrangements, the lens structure 50 is disposed at a unit specific position so as to correctly or optimally align the light source module 10 with the photonic component 20.

In some arrangements, the lens structure 50 includes a supporting plate 40 and a lens 30 connected to the supporting plate 40. In some arrangements, the supporting plate 40 is connected to the light source module 10 through an adhesive element 60. In some arrangements, the lens 30 of the lens structure 50 is configured to define an optical path between the waveguide 120A of the light source module 10 and the waveguide 220 of the photonic component 20. In some arrangements, the lens 30 is configured to change the propagation direction of the optical signal from the direction DR1 to a direction DR1A along a path O1A (or an optical path) between the lens 30 and the optical guiding element 70. In some arrangements, the direction DR1A is different from the direction DR1 and the direction DR2. In some arrangements, the lens 30 is spaced apart from the substrate 100.

The optical guiding element 70 (also referred to as “an adjusting element”) may be stacked over the photonic component 20. In some arrangement, the optical guiding element 70 is configured to adjust the propagation direction of the optical signal from the direction DR1 to the direction DR2. In some arrangement, the optical guiding element 70 is configured to adjust the propagation direction of the optical signal from the direction DR1A to the direction DR2. The optical guiding element (or the adjusting element) may include a prism, a reflective layer, a waveguide component, a beam splitter, or a combination thereof. In some arrangements, the optical guiding element 70 is or includes a prism. The optical guiding element 70 has a top surface 701 and a surface 705 (or a reflective surface) inclined with respect to or non-parallel to the top surface 701. In some arrangements, the lens structure 50 is disposed between the light source module 10 and the optical guiding element 70, and the surface 705 (or the reflective surface) is configured to reflect the optical signal from the lens structure 50 to the photonic component 20. In some arrangements, the lens structure 50 (or the lens 30) is closer to the light source module 10 (or the light source 140) than the optical guiding element 70 (or the surface 705) is. According to some arrangements of the present disclosure, with the above design, a light beam from the light source 140 can be focused by the lens 30 then reflected by the surface 705 (or the reflective surface). Therefore, the beam size of the light beam can be adjusted and controlled to be within a relatively small area, and thus most of or substantially all of the energy of the light beam can be coupled to the photonic component 20.

In some arrangements, the lens structure 50 (or the lens 30) and the optical guiding element 70 (or the prism) collectively construct an optical guiding structure adjacent to the light source module 10 and configured to guide one or more optical signals to the photonic component 20. In some arrangements, the substrate 100 supports the photonic component 20 and the optical guiding structure. In some arrangements, the optical guiding structure is at least partially supported by the photonic component 20. The optical guiding structure may be configured to couple one or more optical signals from the light source module 10 to the photonic component 20. The optical guiding structure may be configured to direct one or more optical signals at least twice within an elevation range horizontally overlapped with the light source module 10. In some arrangements, the optical guiding structure includes a first element (e.g., the lens 30) configured to focus one or more optical signals. The first element may be referred to as a focusing element or a first directing element. The first directing element may be configured to focus the one or more optical signals. The focusing element (or the lens 30) may be supported by the light source module 10. In some arrangements, the optical guiding structure further includes a second element (e.g., the optical guiding element 70 or the prism) configured to direct the one or more optical signals. The second element may be referred to as a reflector element or a second directing element. The reflector element (or the optical guiding element 70 or the prism) may be supported by the photonic component 20. In some arrangements, the reflector element is disposed at an optical transmission path between the focusing element and the photonic component 20. The term “directing” may refer to focusing, changing one or more transmission paths, reflecting, and or splitting of optical signals (or lights). In some arrangements, the first element (e.g., the lens 30) is closer to the light source module 10 than the second element (e.g., the optical guiding element 70 or the prism) is. In some arrangements, the first element (e.g., the lens 30) and the second element (e.g., the optical guiding element 70 or the prism) are non-overlapped vertically. In some arrangements, a portion of the second element (e.g., the optical guiding element 70 or the prism) overlaps an optical receiving area of the photonic component 20.

According to some arrangements of the present disclosure, the light source module includes optical components that are passively aligned, and the light source module is then actively aligned with the photonic component by the lens structure (or the lens). Therefore, the time and the cost for actively aligning the optical components within the light source module can be reduced. In addition, the lens structure (or the lens) has a relatively simple structure, less weight, and a relatively small volume, whereby moving the lens structure (or the lens) to perform the active alignment process is easier and less time-consuming than moving the entire light source module.

In addition, according to some arrangements of the present disclosure, the light source module and the optical guiding element are stacked over the photonic component, and the optical guiding element is configured to adjust the propagation direction of the optical signal. Therefore, the optical signal from the light source module can be received by the photonic component stacked under the light source module, and thus the package size as well as the package volume can be reduced. In addition, the optical guiding element can increase the design flexibility, especially when the photonic component is configured to receive an optical signal through edge coupling and stacked under the light source module.

Furthermore, when an emitted optical signal is a divergent light, the divergent angle may result in greater beam sizes of the optical signal when the divergent light is reflected during transmission. As a result, if the receiving area fails to cover the beam size of the optical signal, optical transmission loss may occur. In contrast, according to some arrangements of the present disclosure, the propagation direction of the optical signal is changed (e.g., by an optical guiding element) after it passes the lens structure. Therefore, the divergent light of the optical signal may be converted to a parallel light beam having a consistent beam size before it is reflected, such that the beam size of the optical signal can be adjusted and controlled to be within a relatively small range. Accordingly, the optical transmission loss can be prevented, the optical efficiency can be increased, and the signal-to-noise (S/N) ratio can be increased.

FIG. 1C is a cross-section of an optoelectronic structure 1C in accordance with some arrangements of the present disclosure. FIG. 1D is a top view of an optoelectronic structure in accordance with some arrangements of the present disclosure. In some arrangements, FIG. 1C is a cross-section along a line 1C-1C′ in FIG. 1D. The optoelectronic structure 1C illustrated in FIGS. 1C-1C is similar to that in FIGS. 1A-1, with differences therebetween as follows.

In some arrangements, the optoelectronic structure 1C further includes a structure 1000 disposed over the substrate 100. The structure 1000 may be referred to as a co-packaged optic structure including a photonic component 1020 and an electronic component 1010 disposed over the photonic component 1020. The electronic component 1010 may be or include an electronic integrated circuit (EIC). The electronic component 1010 may be electrically connected to the photonic component 1020, e.g., through connection elements 1010c (e.g., solder balls). In some arrangements, the photonic component 1020 is attached or affixed to the substrate 100 by an adhesive elements 1020A. In some arrangements, the photonic component 1020 includes a substrate layer 210, waveguides 220A and 220B, and a dielectric layer 260. In some arrangements, one or more optical signals from the waveguide 220 of the photonic component 20 may be transmitted or coupled to an external component through the structure 1000. In some arrangements, one or more optical signals from an external component may be transmitted or coupled to the waveguide 220 of the photonic component 20 through the structure 1000. The waveguide 220 of the photonic component 20 may be optically coupled to the waveguide 220A of the photonic component 1020. The structure 1000 may further include an optical component 1100 (e.g., optical fibers) coupled to the waveguide 220B. Optical signals (e.g., logic signals) from the photonic component 1020 may be coupled to an external component through the optical component 1100. Optical signals (e.g., logic signals) from an external component may be coupled to the photonic component 1020 through the optical component 1100.

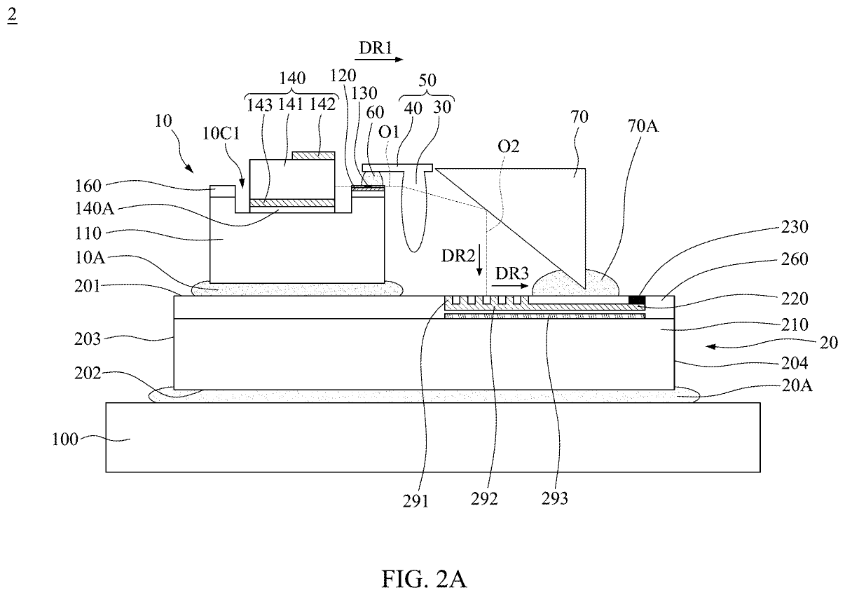

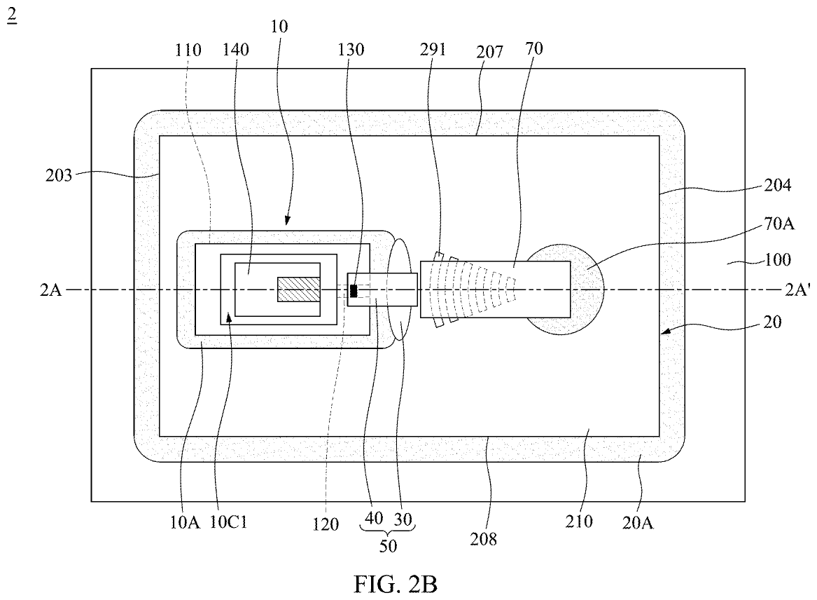

FIG. 2A is a cross-section of an optoelectronic structure 2 in accordance with some arrangements of the present disclosure. FIG. 2B is a top view of an optoelectronic structure 2 in accordance with some arrangements of the present disclosure. In some arrangements, FIG. 2A is a cross-section along a line 2A-2A′ in FIG. 2B. The optoelectronic structure 2 illustrated in FIGS. 2A-2B is similar to that in FIGS. 1A-1B, with differences therebetween as follows.

In some arrangements, the light source module 10 of the optoelectronic structure 2 does not include the cavity 10C2, the waveguide 120A, and the photodetector 130A. In some arrangements, the active optical element (e.g., the SOA) may be integrated into the circuit layers of the substrate layer 110.

In some arrangements, the photonic component 20 is configured to receive an optical signal from the light source module 10 through grating coupling. In some arrangements, the photonic component 20 is configured to receive an optical signal from the light source module 10 by the surface 201 (or the top surface).

In some arrangements, the photonic component 20 further includes one or more elements configured to adjust the propagation direction of the optical signal. In some arrangements, the photonic component 20 further includes a grating coupler 291, a waveguide 292 connected to the grating coupler 291 and the waveguide 220, and a reflective layer 293 between the substrate layer 210 and the grating coupler 291. In some arrangements, the grating coupler 291 is configured to adjust the propagation direction of the optical signal from the direction DR2 to the direction DR3. In some arrangements, an extending direction of the waveguide 292 is substantially parallel to the direction DR3.

According to some arrangements of the present disclosure, the grating coupler is configured to receive the optical signal directed from the optical guiding element. Since the manufacturing process for the grating coupler, the waveguide, and the reflective layer can be integrated into the manufacturing process for the photonic component, and no cavity or recess is required to be formed in the photonic component. Therefore, the manufacturing process is simplified. Moreover, the reflective layer 293 can further reflect optical signals back to the waveguides 292 and 220. Therefore, the loss can be reduced, and the optical transmission efficiency can be increased.

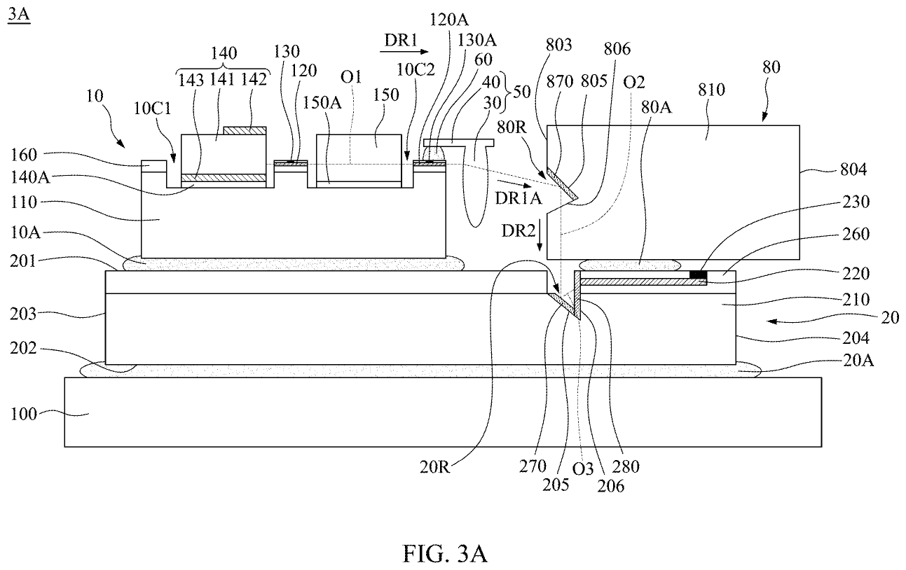

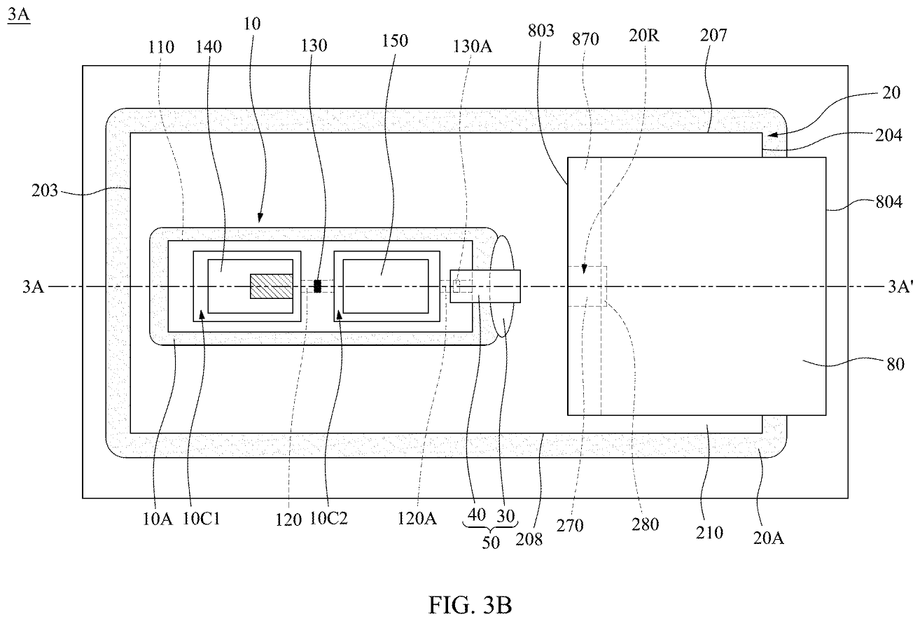

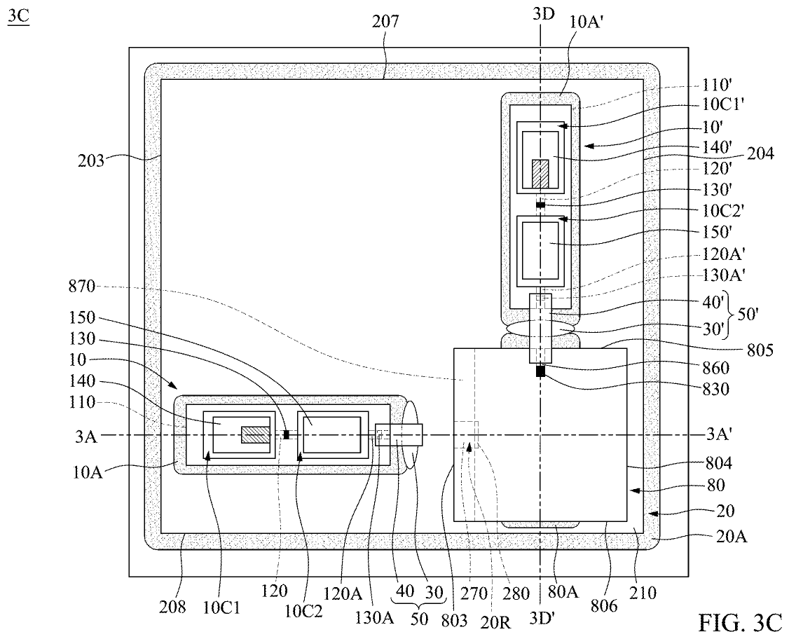

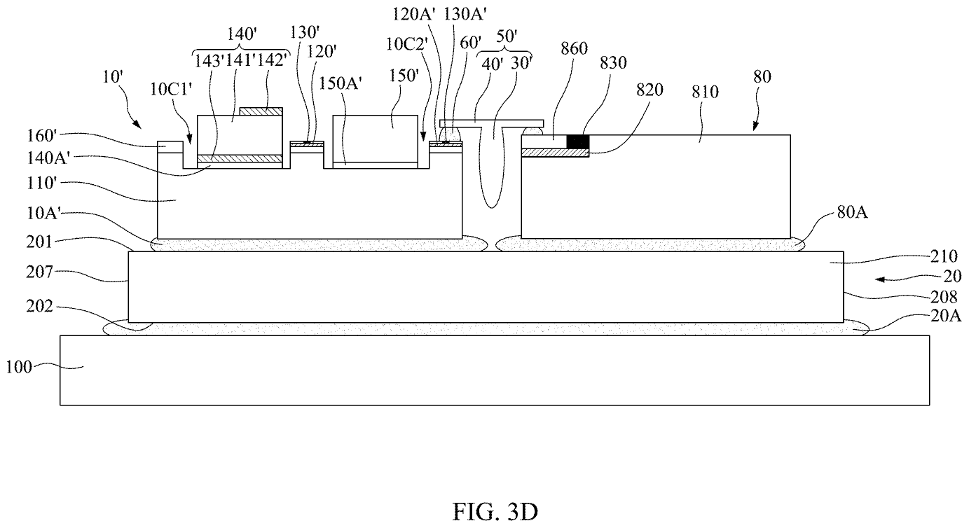

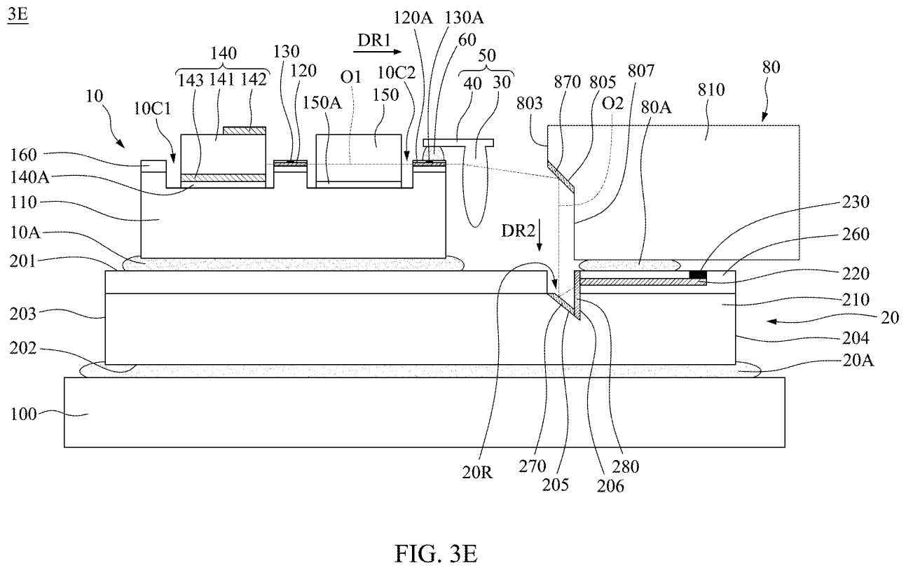

FIG. 3A is a cross-section of an optoelectronic structure 3A in accordance with some arrangements of the present disclosure. FIG. 3B is a top view of an optoelectronic structure 3A in accordance with some arrangements of the present disclosure. In some arrangements, FIG. 3A is a cross-section along a line 3A-3A′ in FIG. 3B. The optoelectronic structure 3A illustrated in FIGS. 3A-3B is similar to that in FIGS. 1A-1B, with differences therebetween as follows.

The optoelectronic structure 3A may include a plurality of optical components stacked over one optical component. In some arrangements, the optoelectronic structure 3A further includes a photonic component 80 stacked over the photonic component 20 and configured to change the propagation direction of the optical signal from the light source module 10. In some arrangements, the photonic component 80 is attached or affixed to the photonic component 20 by an adhesive element 80A. The photonic component 80 may include a portion overhanging an edge of the photonic component 20. In some arrangements, the photonic component 80 includes a substrate layer 810 and a reflective layer 870 (also referred to as “a reflective element”). The substrate layer 810 may include a silicon-based layer and one or more circuit layers formed in the silicon-based layer. The circuit layers may include a driver circuit (e.g., a photonic integrated circuit; PIC). The circuit layers may include an amplifier (e.g., a semiconductor optical amplifier; SOA) for increasing the intensity of the optical signal received by the photonic component 80. The reflective layer 870 may be or include a metal layer. The photonic component 80 may have a cavity 80R (also referred to as “a recess”) facing the light source module 10. The reflective layer 870 may be disposed in the cavity 80R. The photonic component 80 may be referred to as an optical guiding element. For example, the optical guiding element of the optoelectronic structure 3A may include a photonic component (i.e., the photonic component 80). In some arrangements, the photonic component 80 is configured to guide an optical signal from the light source module 10 to the photonic component 20.

In some arrangements, the photonic component 80 is configured to adjust a propagation path of the optical signal from the light source module 10 to the photonic component 20. In some arrangements, the photonic component 80 has a surface 803 (also referred to as “a lateral surface”) facing the light source module 10 and a surface 804 opposite to the surface 803. The cavity 80R may be recessed from the surface 803. The photonic component 80 further has a surface 805 recessed from the surface 803 or inclined with respect to the surface 803. The surface 805 may be or include a reflective surface. The reflective layer 870 may be disposed or formed on the surface 805. In some arrangements, the reflective layer 870 (or the reflective element) is exposed by the surface 803 (or the lateral surface). In some arrangements, the surface 805 (or the reflective layer 870) is configured to adjust the propagation direction of the optical signal from the direction DR1 (or the direction DR1A) to the direction DR2. The photonic component 80 further has a surface 806 recessed from the surface 803 or inclined with respect to the surface 803. In some arrangements, the surface 806 is spaced apart from and substantially perpendicular to the surface 805. In some arrangements, the surface 805 (or the inclined surface) is configured to reflect the optical signal from the light source module 10 to the surface 806. In some arrangements, the surface 805 is configured to reflect the optical signal from the light source module 10 to reach the surface 806 and pass through a portion of the substrate layer 810 of the photonic component 80. In some arrangements, the photonic components 20 and 80 collectively construct a photonic device, the photonic component 80 is configured to receive an optical signal and does not require a light source connected thereto, and the photonic component 20 is configured to emit an optical signal.

In some arrangements, the lens structure 50 (or the lens 30) and the photonic component 80 collectively construct an optical guiding structure adjacent to the light source module 10 and configured to guide one or more optical signals to the photonic component 20. In some arrangements, the substrate 100 supports the photonic component 20 and the optical guiding structure. In some arrangements, the optical guiding structure is at least partially supported by the photonic component 20. The optical guiding structure may be configured to couple one or more optical signals from the light source module 10 to the photonic component 20. The optical guiding structure may be configured to direct one or more optical signals at least twice within an elevation range horizontally overlapped with the light source module 10. In some arrangements, the optical guiding structure includes a first element (e.g., the lens 30) configured to focus one or more optical signals. The first element may be referred to as a focusing element. The focusing element (or the lens 30) may be supported by the light source module 10. In some arrangements, the optical guiding structure further includes a second element (e.g., the photonic component 80) configured to direct the one or more optical signals. The second element may be referred to as a reflector element. The reflector element (or the photonic component 80) may be supported by the photonic component 20. In some arrangements, the reflector element is located at an optical transmission path between the focusing element and the photonic component 20. The term “directing” may refer to focusing, changing one or more transmission paths, reflecting, and or splitting of optical signals (or lights). In some arrangements, the first element (e.g., the lens 30) is closer to the light source module 10 than the second element (e.g., photonic component 80) is. In some arrangements, the first element (e.g., the lens 30) and the second element (e.g., photonic component 80) are non-overlapped vertically. In some arrangements, a portion of the second element (e.g., photonic component 80) overlaps an optical receiving area of the photonic component 20.

FIG. 3C is a top view of an optoelectronic structure in accordance with some arrangements of the present disclosure. FIG. 3D is a cross-section of an optoelectronic structure in accordance with some arrangements of the present disclosure. In some arrangements, FIG. 3A is a cross-section along a line 3A-3A′ in FIG. 3C, and FIG. 3D is a cross-section along a line 3D-3D′ in FIG. 3C. The optoelectronic structure 3C illustrated in FIGS. 3C-3D is similar to that in FIGS. 1A-1B, with differences therebetween as follows.

The optoelectronic structure 3C may further include a light source module 10′ stacked over the photonic component 20 and configured to transmit an optical signal to the photonic component 80. In some arrangements, the light source module 10′ is disposed over (e.g., affixed to) the photonic component 20 by an adhesive element 10A′. In some arrangements, the light source module 10′ includes a substrate layer 110′, waveguides 120′ and 120A′, photodetectors 130′ and 130A′, a light source 140′, an active optical element 150′, and a dielectric layer 160′. The substrate layer 110′ may include a silicon-based layer and one or more circuit layers formed in the silicon-based layer. The circuit layers may include a driver circuit (e.g., a laser diode driver circuit). The substrate layer 110′ and the dielectric layer 160′ collectively define cavities 10C1′ and 10C2′. The waveguides 120′ and 120A′ may be formed on the dielectric layer 160′, and the photodetectors 130′ and 130A′ may be formed over the dielectric layer 160′ and optically coupled to the waveguides 120′ and 120A′, respectively. The photodetector 130′ may be configured to detect one or more optical signals transmitted through the waveguide 120′, and the photodetector 130A′ may be configured to detect one or more optical signals transmitted through the waveguide 120A′. The dielectric layer 160′ may serve as a protective layer or a passivation layer for the waveguides 120′ and 120A′ and the photodetectors 130′ and 130A′. The light source 140′ may be or include a laser diode. The light source 140′ may include a light-emitting layer 141′ and electrodes 142′ and 143′. The light source 140′ may be adhered to a bottom of the cavity 10C1′ by an adhesive layer 140A′. The active optical element 150′ may be adhered to a bottom of the cavity 10C2′ by an adhesive layer 150A′. The active optical element 150′ may include an amplifier, e.g., a semiconductor optical amplifier (SOA). The active optical element 150′ may be passively aligned by the waveguide 120′ and/or 120A′.

In some arrangements, the photonic component 80 further includes a waveguide 820, a photodetector 830, and a dielectric layer 860. The waveguide 820 may be formed on a portion of the substrate layer 810, and the photodetector 830 may be formed on and optically coupled to the waveguide 820. The photodetector 830 may be configured to detect and/or monitor one or more optical signals transmitted from the waveguide 820. The dielectric layer 860 may serve as a protective layer or a passivation layer for the waveguide 820 and the photodetector 830. In some arrangement, the photonic component 80 further has a surface 805 (also referred to as “a lateral surface”) distinct from and adjacent to the surface 803. In some arrangements, the surface 803 faces the light source module 10, and the surface 805 faces the light source module 10′. In some arrangements, the reflective layer 870 is exposed by the surface 803, and the waveguide 820 is exposed by the surface 805. In some arrangements, the reflective layer 870 is configured to reflect the optical signal (also referred to as “first optical signal”) from the light source module 10 to the photonic component 20, and the waveguide 820 is configured to receive the optical signal (also referred to as “second optical signal”) from the light source module 10′. In some arrangements, the light source module 10 serves as a light source for the photonic component 20, and the light source module 10′ serves as a light source for the photonic component 80.

In some arrangements, the optical guiding structure (or the photonic component 80) may be configured to direct a plurality of optical signals received from different directions. In some arrangements, the photonic component 80 may include a plurality of optical signal guiding portions configured to guide the optical signals from different light sources (e.g., the light source modules 10 and 10′) toward the photonic component 20 disposed under the photonic component 80. One of the optical signal guiding portions may be referred to as or include the cavity 80R and the reflective layer 870 as illustrated in FIGS. 3A-2B, and another one of the optical signal guiding portions may be referred to as or include the waveguide 820 as illustrated in FIG. 3D. In some arrangements, the optical signals (or the lights) provided from the light source modules 10 and 10′ have different wavelengths. In some arrangements, the photonic component 20 may include terminal structures configured to optically couple to the optical signal guiding portions of the photonic component 80 and waveguides corresponding to the terminal structures. For example, the photonic component 20 may include a terminal structure including the cavity 20R, the reflective layer 270, and the optical isolator 280, and the waveguide 220 corresponding thereto, as illustrated in FIG. 3A. For example, the photonic component 20 may further include a terminal structure including a grating coupler 291 as illustrated in FIG. 2A. According to some arrangements of the present disclosure, with the above design of the optical signal guiding portions, the optical signal transmission efficiency can be increased.

FIG. 3E is a cross-section of an optoelectronic structure 3E in accordance with some arrangements of the present disclosure. The optoelectronic structure 3E illustrated in FIG. 3E is similar to that in FIGS. 3A-3B, with differences therebetween as follows.

The optoelectronic structure 3E is similar to the optoelectronic structure 3A illustrated in FIG. 3A, except that the photonic component 80 does not have the surface 806 inclined with respect to the surface 803. In some arrangements, the photonic component 80 has a surface 807 recessed from the surface 803 and connected to the surface 805. In some arrangements, the optical signal reflected by the surface 805 (or the reflective layer 870) propagates directly to the surface 205 (or the reflective layer 270) without passing a portion of the substrate layer 810.

According to some arrangements of the present disclosure, the photonic component includes a structure feature (e.g., the recess, the inclined surfaces, the reflective surface, and etc.) configured to adjust the propagation direction of an optical signal from the light source module. With the above design, the photonic component not only can provide the desired photonic functions in the optoelectronic structure but also can serve as an optical guiding element for providing a light source to another photonic component. Therefore, the number of photonic components integrated in one optoelectronic structure can be increased, additional optical guiding elements can be omitted, and thus the package size can be reduced.

In addition, according to some arrangements of the present disclosure, the photonic components may share one light source module by receiving optical signals from the same light source module by providing one of the photonic components having a beam splitter. Therefore, the number of the light source modules and the number of the optical guiding elements can be both reduced, and thus the package size can be further reduced.

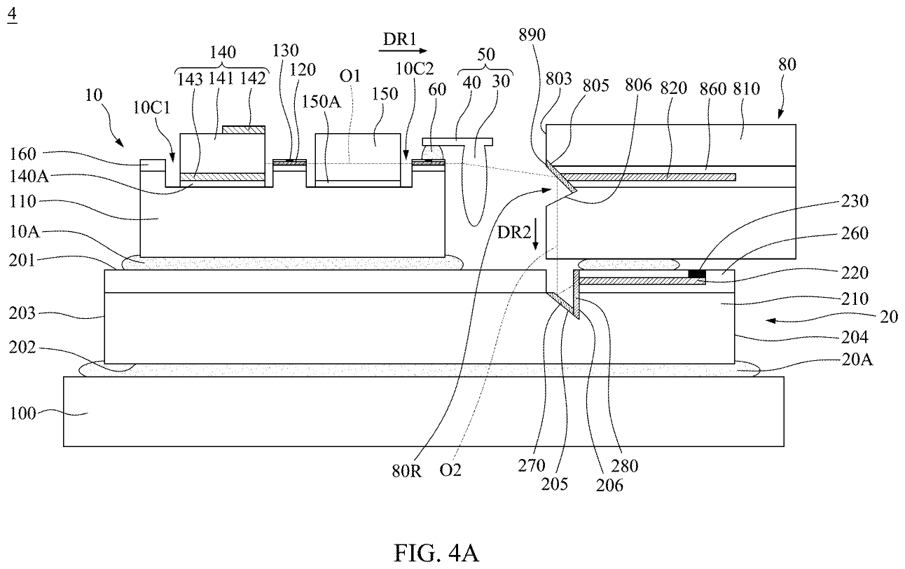

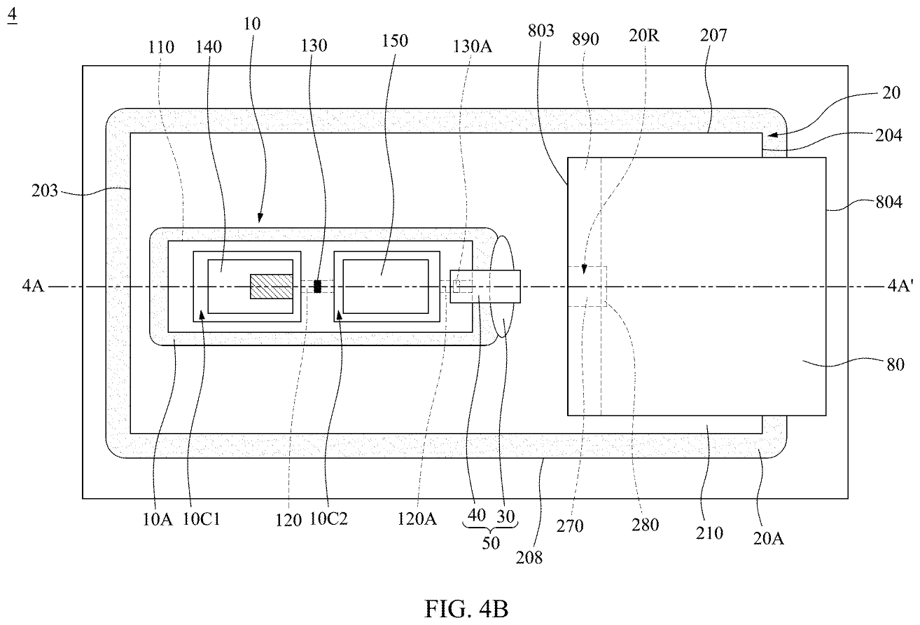

FIG. 4A is a cross-section of an optoelectronic structure 4 in accordance with some arrangements of the present disclosure. FIG. 4B is a top view of an optoelectronic structure 4 in accordance with some arrangements of the present disclosure. In some arrangements, FIG. 4A is a cross-section along a line 4A-4A′ in FIG. 4B. The optoelectronic structure 4 illustrated in FIGS. 4A-4B is similar to that in FIGS. 1A-1B, with differences therebetween as follows.

In some arrangements, the photonic component 80 is configured to adjust the propagation direction of an optical signal (also referred to as “a first optical signal”) from the light source module 10 to the photonic component 20, and the photonic component 80 is further configured to receive an optical signal (also referred to as “a second optical signal”) from the light source module 10. In some arrangements, the light source module 10 serves as a light source for both of the photonic component 20 and the photonic component 80.

In some arrangement, the photonic component 80 includes a beam splitter 890 configured to split an optical signal emitted from the light source module 10 into two optical signals (e.g., the first optical signal and the second optical signal) propagating in different directions. The beam splitter 890 is configured to split an optical signal emitted from the light source module 10 into two different optical signals. A ratio of the intensities of the two optical signals is about 1; however, the ratio may vary according to actual applications and is not limited thereto. The beam splitter 890 is configured to split an optical signal emitted from the light source module 10 into two polarized optical signals orthogonal to each other (e.g., a p-polarization beam and an s-polarization beam). In some arrangements, one of the two optical signals generated by the beam splitter 890 is reflected and propagates in the direction DR2 to the photonic component 20, and the other one of the two optical signals is received by the waveguide 820 of the photonic component 80. In some arrangements, the waveguide 820 is exposed to the cavity 80R and configured to receive the optical signal. In some arrangements, the reflective layer 270 at least partially vertically overlaps the beam splitter 890.

In some arrangements, the lens structure 50 (or the lens 30) and the photonic component 80 collectively construct an optical guiding structure adjacent to the light source module 10 and configured to guide one or more optical signals to the photonic component 20. In some arrangements, the substrate 100 supports the photonic component 20 and the optical guiding structure. In some arrangements, the optical guiding structure is at least partially supported by the photonic component 20. The optical guiding structure may be configured to couple one or more optical signals from the light source module 10 to the photonic component 20. The optical guiding structure may be configured to direct one or more optical signals at least twice within an elevation range horizontally overlapped with the light source module 10. In some arrangements, the optical guiding structure includes a first element (e.g., the lens 30) configured to focus one or more optical signals. The first element may be referred to as a focusing element. The focusing element (or the lens 30) may be supported by the light source module 10. In some arrangements, the optical guiding structure further includes a second element (e.g., the photonic component 80) configured to direct the one or more optical signals. The second element may be referred to as a reflector element. The reflector element (or the photonic component 80) may be supported by the photonic component 20. In some arrangements, the reflector element is located at an optical transmission path between the focusing element and the photonic component 20. The term “directing” may refer to focusing, changing one or more transmission paths, reflecting, and or splitting of optical signals (or lights). In some arrangements, the first element (e.g., the lens 30) is closer to the light source module 10 than the second element (e.g., photonic component 80) is. In some arrangements, the first element (e.g., the lens 30) and the second element (e.g., photonic component 80) are non-overlapped vertically. In some arrangements, a portion of the second element (e.g., photonic component 80) overlaps an optical receiving area of the photonic component 20. In some arrangements, the second element (e.g., photonic component 80) includes a waveguide 820 configured to receive one or more optical signals by a beam splitter 890.

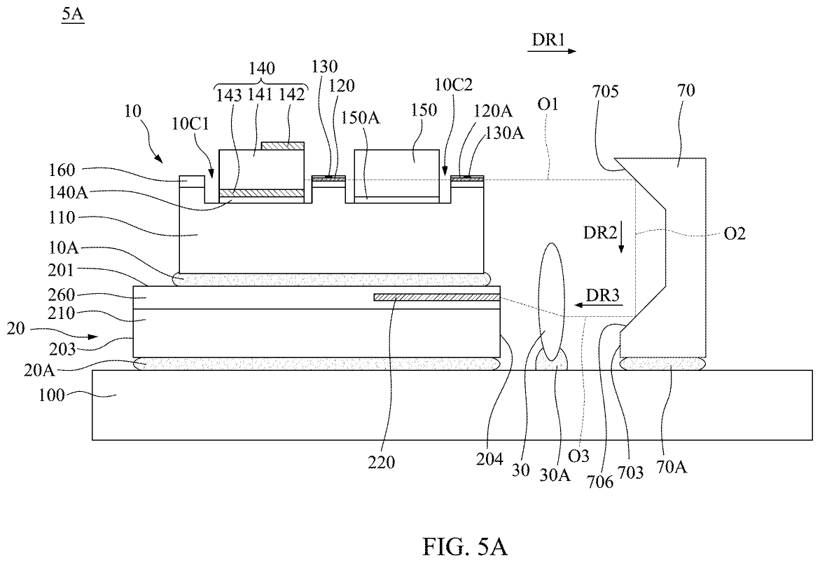

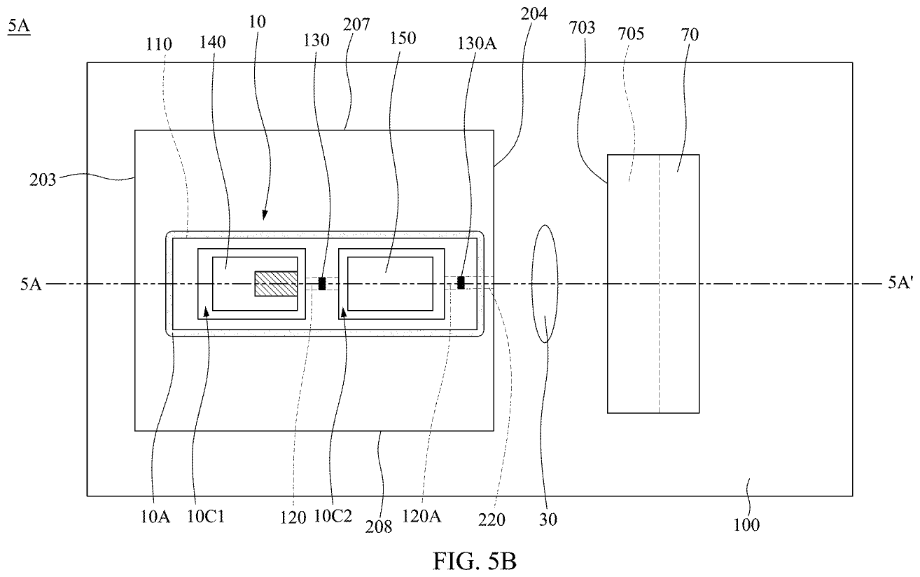

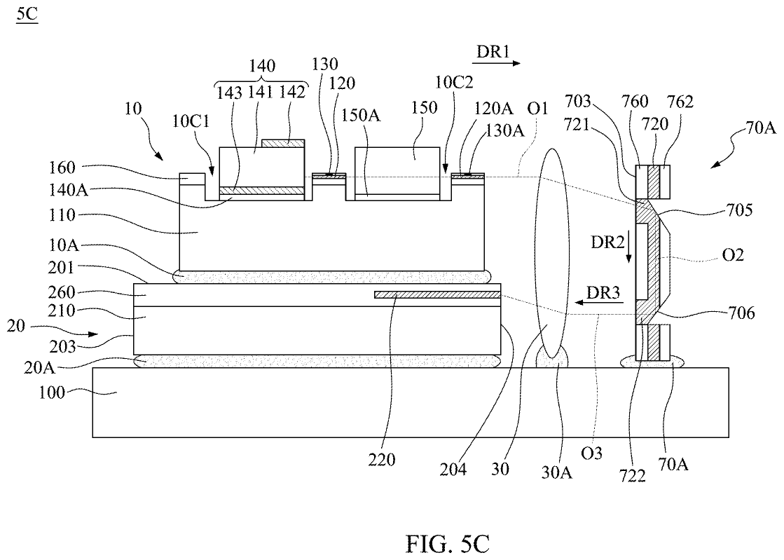

FIG. 5A is a cross-section of an optoelectronic structure 5A in accordance with some arrangements of the present disclosure. FIG. 5B is a top view of an optoelectronic structure 5A in accordance with some arrangements of the present disclosure. In some arrangements, FIG. 5A is a cross-section along a line 5A-5A′ in FIG. 5B. The optoelectronic structure 5A illustrated in FIGS. 5A-5B is similar to that in FIGS. 1A-1B, with differences therebetween as follows.

In some arrangements, the optical guiding element 70 (or the adjusting element) is disposed at a same lateral side of the light source module 10 and the photonic component 20. In some arrangements, the lens 30 (or the optical alignment component) is disposed between the optical guiding element 70 and the photonic component 20. In some arrangements, the optical guiding element 70 is configured to adjust the propagation direction of the optical signal from the light source module 10 from the direction DR1 to the direction DR2, and further from the direction DR2 to the direction DR3.

In some arrangements, the optical guiding element 70 has two surfaces 705 and 706 that are recessed from and inclined with respect to the surface 703 that faces the light source module 10. In some arrangements, the surfaces 705 and 706 may be referred to as reflective elements. In some arrangements, the surface 705 (or the reflective element) is configured to adjust the propagation direction of the optical signal from the direction DR1 to the direction DR2, and the surface 706 (or the reflective element) is configured to further adjust the propagation direction of the optical signal from the direction DR2 to the direction DR3. In some arrangements, the surface 706 is configured to reflect the optical signal to the lens 30. In some arrangements, the waveguide 220 of the photonic component 20 is exposed by the surface 204 (or the lateral surface) of the photonic component 20. In some arrangements, the surface 706 is configured to reflect the optical signal to passing the lens 30 and received by the waveguide 220 of the photonic component 20. In some arrangements, the optical guiding element 70 is or includes a prism. The optical guiding element 70 may be referred to as a prism element. In some arrangements, the waveguide 220 is disposed over the substrate layer 210. In some other arrangements, the waveguide 220 may be embedded in the dielectric layer 260 and disposed between the substrate 100 and the substrate layer 210. In some arrangements, the optical guiding structure is horizontally overlapped with the light source module 10 and the photonic component 20.

FIG. 5C is a cross-section of an optoelectronic structure 5C in accordance with some arrangements of the present disclosure. The optoelectronic structure 5C illustrated in FIG. 5C is similar to that in FIGS. 5A-5B, with differences therebetween as follows.

In some arrangements, the optoelectronic structure 5C is similar to the optoelectronic structure 5A, except that the optical guiding element 70A has a structure different from that of the optical guiding element 70.

In some arrangements, the lens 30 includes curved surfaces on opposite sides. In some arrangements, the lens 30 is or includes a micro-lens, a saw-tooth Fresnel lens, a multilevel diffractive lens, or a combination thereof.

In some arrangements, the optical guiding element 70A includes a waveguide 720, optical terminals 721 and 722, and cladding layers 760 and 762. The optical guiding element 70A may be referred to as a waveguide component or a waveguide device. The optical terminals 721 and 722 are exposed by the surface 703 and facing the lens 30. The optical guiding element 70A further has two recesses defining the surfaces 705 and 706 that are inclined with respect to the surface 703. In some arrangements, the surfaces 705 and 706 may be referred to as reflective elements. In some arrangements, the surface 705 is configured to adjust the propagation direction of the optical signal from the direction DR1 to the direction DR2, and the surface 706 is configured to further adjust the propagation direction of the optical signal from the direction DR2 to the direction DR3. In some arrangements, the surface 705 is configured to reflect the optical signal from the lens 30 and received by the optical terminal 721. In some arrangements, the surface 706 is configured to reflect the optical signal to passing the optical terminal 722 to the lens 30. In some arrangements, the surface 706 is configured to reflect the optical signal to passing the lens 30 and received by the waveguide 220 of the photonic component 20.

According to some arrangements of the present disclosure, the optical guiding element includes structure features that can reflect the optical signal multiple times until it is received by the photonic component. Therefore, there is no need to form optical guiding structures on or in the photonic component, and thus the manufacturing process and the cost for the photonic component can be reduced. In addition, the optical guiding element is or includes a dummy device (e.g., a prism element or a waveguide component) that can be manufactured separately before it is bonded to the substrate. Therefore, the manufacturing process of the optoelectronic structure can be simplified, and the yield can be improved.

Furthermore, according to some arrangements of the present disclosure, the optical signal emitted from the light source module passes the lens (or the lens structure) twice before it is received by the photonic component. Therefore, the divergent light of the optical signal can be converted by the lens into a parallel light beam, and after the parallel light beam is reflected and passes the lens (or the lens structure) again, the parallel light beam may be further focused into a focused light beam. Accordingly, the waveguide of the photonic component may have a relatively small size, which is advantageous to reducing the device size.

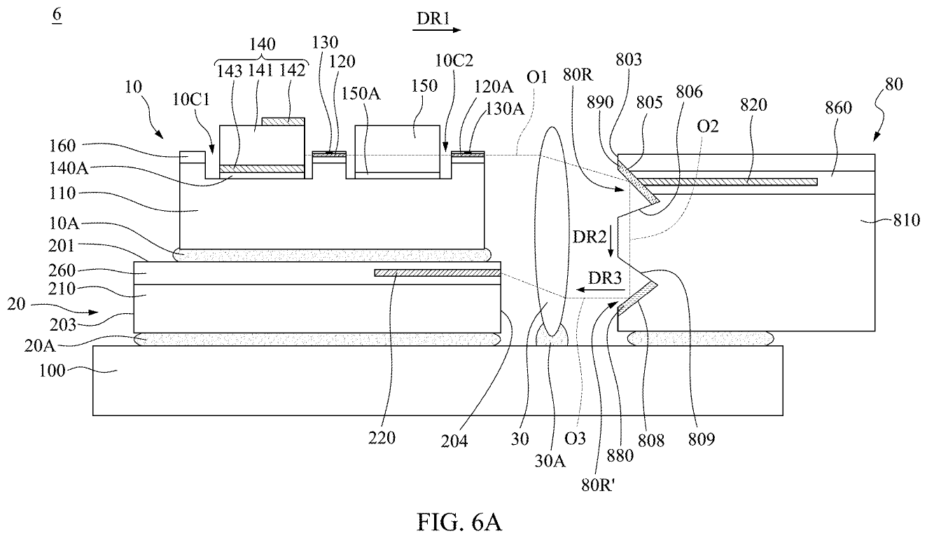

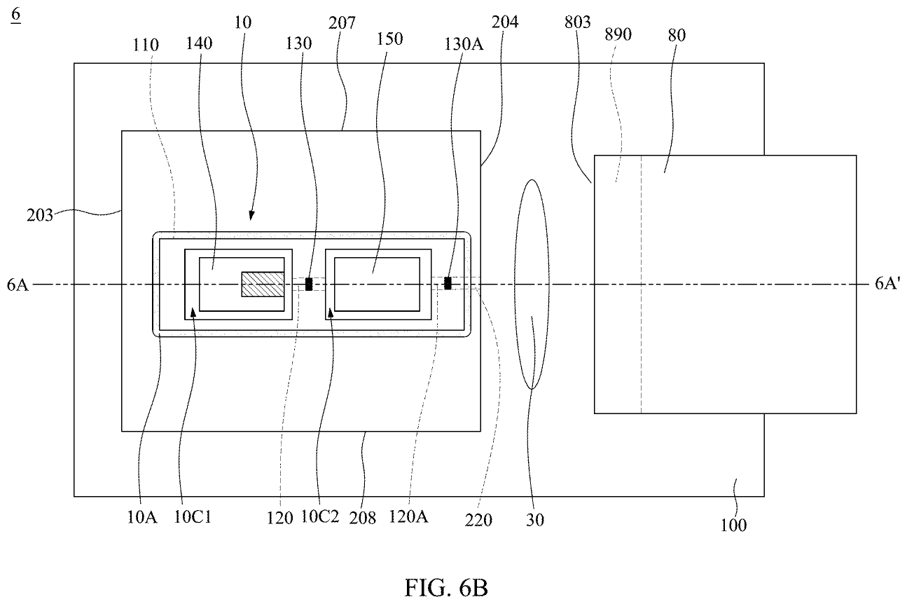

FIG. 6A is a cross-section of an optoelectronic structure 6 in accordance with some arrangements of the present disclosure. FIG. 6B is a top view of an optoelectronic structure 6 in accordance with some arrangements of the present disclosure. In some arrangements, FIG. 6A is a cross-section along a line 6A-6A′ in FIG. 6B. The optoelectronic structure 6 illustrated in FIGS. 6A-6B is similar to that in FIGS. 5A-5B, with differences therebetween as follows.

In some arrangements, the photonic component 80 has a structure similar to that illustrated in FIG. 4A, except that the photonic component 80 of the optoelectronic structure 6 further includes a recess 80R′ and a reflective layer 880 (also referred to as “a reflective element”). In some arrangements, the reflective layer 880 is configured to reflect the optical signal to the waveguide 220 of the photonic component 20.

In some arrangements, the cavities 80R and 80R′ are recessed from the surface 803. In some arrangements, the waveguide 820 is exposed to the cavity 80R and configured to receive the optical signal from the light source module 10 (e.g., the polarized optical signal generated by the beam splitter 890). In some arrangements, the photonic component 80 further has two surfaces 808 and 809 that are recessed from and inclined with respect to the surface 803 that faces the photonic component 20. In some arrangements, the reflective layer 880 is disposed or formed on the surface 808. In some arrangements, the reflective layer 880 at least partially vertically overlaps the beam splitter 890.

In some arrangements, the photonic component 80 is configured to adjust the propagation direction of the optical signal from the direction DR1 to the direction DR2, and further from the direction DR2 to the direction DR3. In some arrangements, the surface 805 (or the beam splitter 890) is configured to adjust the propagation direction of the optical signal from the direction DR1 to the direction DR2, and the surface 806 (or the reflective layer 880) is configured to further adjust the propagation direction of the optical signal from the direction DR2 to the direction DR3.

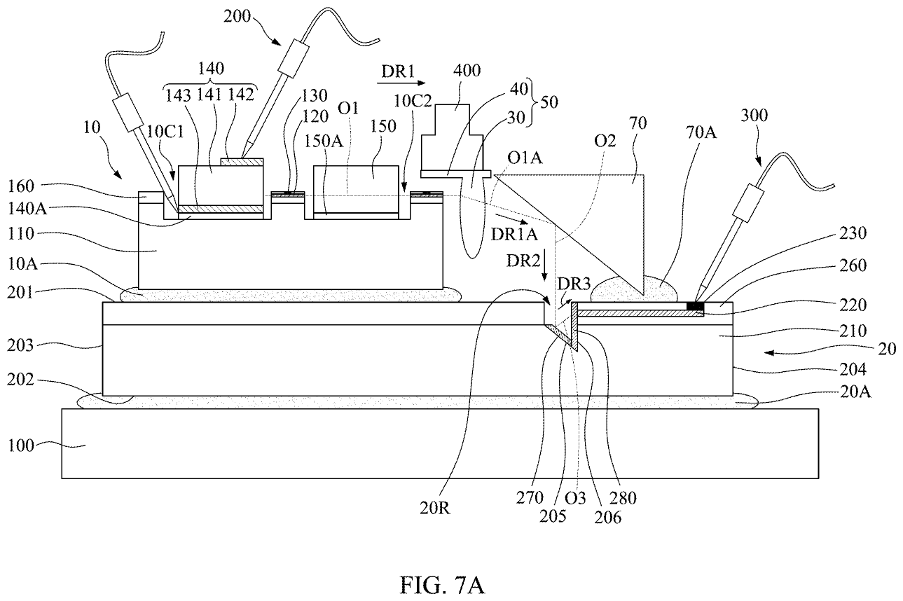

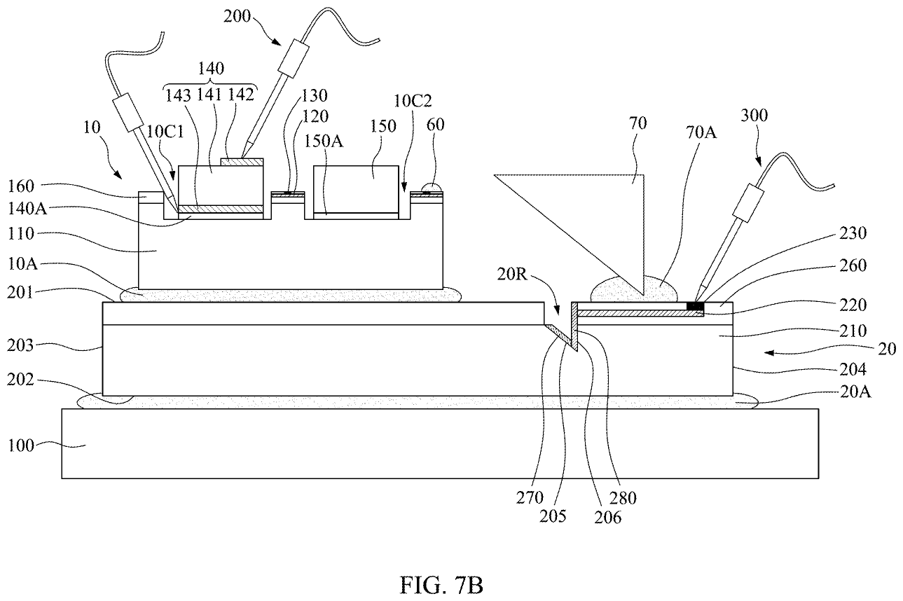

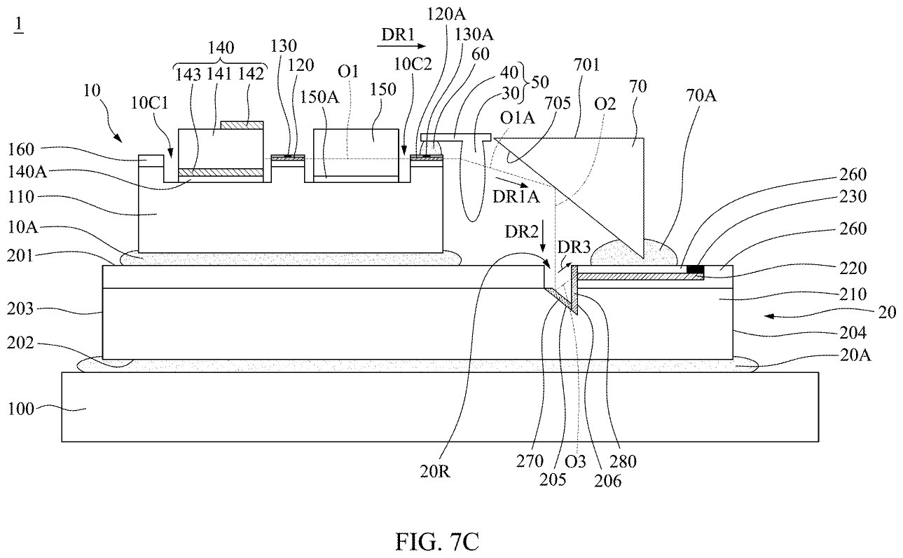

FIG. 7A, FIG. 7B, and FIG. 7C illustrate various stages of an exemplary method for manufacturing an optoelectronic structure in accordance with some arrangements of the present disclosure.

Referring to FIG. 7A, a photonic component 20 may be disposed on or affixed to a substrate 100, a light source module 10 may be disposed on or affixed to the photonic component 20, and an optical guiding element 70 may be disposed on or affixed to the photonic component 20. In some arrangements, the light source module 10 is passively aligned with the optical guiding element 70. Next, the light source module 10 may be connected to a power supply configured to provide power to turn on the light source 140. Probes 200 (or terminals) of the power supply may be connected to the electrodes 142 and 143 of the light source 140 (or the laser diode). The photonic component 20 may be connected to a device that is configured to receive detected and/or monitored results of optical signals from the photodetector 230. A probe 300 (or a terminal) of the device may be connected to the photodetector 230 of the photonic component 20.

Next, still referring to FIG. 7A, an active alignment between the light source module 10 and the photonic component 20 may be performed using a lens structure 50 (or a lens). In some arrangements, aligning (or actively aligning) the light source module 10 with the photonic component 20 includes or is performed by moving the lens structure 50 to actively align the waveguide 120A of the light source module 10 with the photonic component 20. In some arrangements, the lens structure 50 may be adjusted to a unit specific position related to the substrate 100 to couple an optical signal from the light source module 10 to the photonic component 20. In some arrangements, the active alignment includes aligning (or actively aligning) an optical path O1A in a direction DR1A between the waveguide 120A and the photonic component 20 by adjusting or moving the lens structure 50 (or the lens 30) to a unit specific position. The lens structure 50 (or the lens 30) may be adjusted by moving the lens structure 50 (or the lens 30) in multiple directions (e.g., in x-axis, y-axis, z-axis, and/or any direction in three-dimensional space) to maximize or optimize the optical signal received and monitored by the photonic component 20. The lens structure 50 (or the lens 30) may be adjusted or moved by a vacuum suction mechanism 400. In some arrangements, it is determined whether the lens structure 50 (or the lens 30) is or has arrived at the unit specific position when the monitored optical signal (or the optical signal being monitored) reaches a predetermined optimization threshold. In some arrangements, the predetermined optimization threshold includes a predetermined intensity, a predetermined pattern, a predetermined intensity distribution, a predetermined signal-to-noise (S/N) ratio, or any combination thereof. In some arrangements, aligning (or actively aligning) the light source module 10 with the photonic component 20 further includes adjusting or moving the lens structure 50 (or the lens 30) without moving positions of the light source module 10, the photonic component 20, and the optical guiding element 70.

Referring to FIG. 7B, after the unit specific position of the lens structure 50 (or the lens 30) is determined, the lens structure 50 (or the lens 30) may be removed from the unit specific position. In some arrangements, the unit specific position is stored in a processing unit of the device that connects to the probe 300 (or terminal). In some arrangements, an adhesive element 60 is then disposed (or positioned) adjacent to the unit specific position. In some arrangements, the position of the adhesive element 60 is determined according to the unit specific position stored in the processing unit. The adhesive element 60 may be or include a photosensitive glue.

Referring to FIG. 7C, the lens structure 50 (or the lens 30) may be guided to contact or be connected to the adhesive element 60 to affix the lens structure 50 (or the lens 30) at the unit specific position through the adhesive element 60. In some arrangements, the adhesive element 60 may be cured (e.g., by UV) to attach (or permanently affix) the lens structure 50 (or the lens 30) at the unit specific position. As such, the optoelectronic structure 1 is formed.

Spatial descriptions, such as “above,” “below,” “up,”, “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to 0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1, less than or equal to ±0.5°, less than or equal to ±0.10, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An optoelectronic structure, comprising:
a carrier;
a first optical component supported by the carrier; and
a second optical component supported by the first optical component and optically coupled to the first optical component.

2. The optoelectronic structure as claimed in claim 1, wherein the first optical component comprises an optical receiving area exposed by the second optical component.

3. The optoelectronic structure as claimed in claim 1, wherein the first optical component comprises a photonic integrated circuit (PIC) including a waveguide.

4. The optoelectronic structure as claimed in claim 1, further comprising an optical guiding structure adjacent to the first optical component and configured to guide an optical signal to the first optical component.

5. The optoelectronic structure as claimed in claim 4, wherein the optical guiding structure is at least partially supported by the first optical component.

6. The optoelectronic structure as claimed in claim 4, wherein the optical guiding structure comprises:
a first element configured to focus the optical signal; and
a second element configured to direct the optical signal.

7. The optoelectronic structure as claimed in claim 6, wherein the first element is closer to the second optical component than the second element is.

8. The optoelectronic structure as claimed in claim 6, wherein the first element and the second element are non-overlapped vertically.

9. The optoelectronic structure as claimed in claim 6, wherein a portion of the second element overlaps an optical receiving area of the first optical component.

10. The optoelectronic structure as claimed in claim 6, wherein the second element is configured to split the optical signal into propagating in multiple directions.

11. The optoelectronic structure as claimed in claim 6, wherein the second element comprises a photonic component including a waveguide configured to receive the optical signal by a beam splitter.

12. An optoelectronic structure, comprising:
a first optical component;
a second optical component disposed over the first optical component; and
an optical guiding structure configured to couple an optical signal from the second optical component to the first optical component and further configured to direct the optical signal at least twice within an elevation range horizontally overlapped with the second optical component.

13. The optoelectronic structure as claimed in claim 12, wherein the optical guiding structure comprises a first directing element configured to focus the optical signal and a second directing element disposed at an optical transmission path between the first directing element and the first optical component.

14. The optoelectronic structure as claimed in claim 13, wherein the first directing element is supported by the second optical component.

15. The optoelectronic structure as claimed in claim 13, wherein the second directing element is supported by the first optical component.

16. The optoelectronic structure as claimed in claim 12, wherein the optical guiding structure is configured to direct a plurality of the optical signals received from different directions.

17. An optoelectronic structure, comprising:
a first optical component; and
a second optical component overlapped with the first optical component, wherein the first optical component is configured to edge couple an optical signal from the second optical component.

18. The optoelectronic structure as claimed in claim 17, further comprising an optical guiding structure horizontally overlapped with the first optical component and the second optical component.

19. The optoelectronic structure as claimed in claim 18, further comprising a carrier supporting the first optical component and the optical guiding structure, wherein the carrier is electrically connected to the second optical component.

20. The optoelectronic structure as claimed in claim 19, wherein the first optical component is disposed between the carrier and the second optical component.
